(19) United States
(12) Patent Application Publication
(10) Pub. No.: US 2026/0213760 A1
(43) Pub. Date: Jul. 23, 2026

(54) FRONT-END CIRCUITRY AND SIGNAL CONVERSION METHOD

(71) Applicant: REALTEK SEMICONDUCTOR CORPORATION, HSINCHU (TW)

(72) Inventor: SHIH-HSIUNG HUANG, Hsinchu (TW)

(21) Appl. No.: 19/422,932

(22) Filed: Dec. 17, 2025

(30) Foreign Application Priority Data
Jan. 23, 2025 (TW) 114103217

(51) Int. Cl. H03M 1/08

(52) U.S. Cl. CPC H03M 1/08

(57) ABSTRACT

A front‑end circuitry includes a first buffer circuit, a first switch, an analog-to-digital converter circuit, a digital-to-analog converter circuit, a second switch, and a subtractor circuit. The first buffer circuit is configured to generate a first buffer signal according to an input signal. The first switch is configured to be turned on according to a control signal, in order to output the first buffer signal as a first signal. The analog‑to‑digital converter circuit is configured to generate a digital code according to the first signal. The digital‑to‑analog converter circuit is configured to generate a feedback signal according to the digital code. The second switch is configured to be turned on according to the control signal, in order to output a second signal according to the input signal. The subtractor circuit is configured to subtract the feedback signal from the second signal to generate an output signal.

### BACKGROUND OF THE INVENTION

### Field of the Invention

The present disclosure relates to front‑end circuitry, and more particularly to front‑end circuitry and a signal conversion method that utilize a buffer circuit to reduce the influence of noise.

### Description of Related Art

In existing analog‑to‑digital converter circuits, sampling circuits, comparator circuits and/or capacitor array circuits generally involve multiple switching operations. These switching operations cause kickback noise that unexpectedly affects an input signal and ultimately result in degradation of quality of an output signal of an analog‑to‑digital converter circuit. In greater detail, generation of kickback noise mainly results from transient voltage or current variations inside a circuit due to switching operations. When these variations couple to a signal input terminal, quality of the input signal is reduced and ultimately results in a lower quality of the output signal. This phenomenon is more significant in high‑speed or high‑precision analog‑to‑digital converter circuits.

### SUMMARY OF THE INVENTION

In some aspects, an object of the present disclosure is to provide, but is not limited to, a front‑end circuitry and a signal conversion method that may utilize a buffer circuit to reduce noise influence, so as to make an improvement to the prior art.

In some aspects, a front‑end circuitry includes a first buffer circuit, a first switch, an analog-to-digital converter circuit, a digital-to-analog converter circuit, a second switch, and a subtractor circuit. The first buffer circuit is configured to generate a first buffer signal according to an input signal. The first switch is configured to be turned on according to a control signal, in order to output the first buffer signal as a first signal. The analog‑to‑digital converter circuit is configured to generate a digital code according to the first signal. The digital‑to‑analog converter circuit is configured to generate a feedback signal according to the digital code. The second switch is configured to be turned on according to the control signal, in order to output a second signal according to the input signal. The subtractor circuit is configured to subtract the feedback signal from the second signal to generate an output signal.

In some aspects, a signal conversion method includes the following operations: generating, by a first buffer circuit, a first buffer signal according to an input signal; turning on a first switch according to a control signal, in order to output the first buffer signal as a first signal through the first switch; generating, by an analog‑to‑digital converter circuit, a digital code according to the first signal; generating, by a digital‑to‑analog converter circuit, a feedback signal according to the digital code; turning on a second switch according to the control signal, in order to output a second signal according to the input signal through the second switch; and subtracting, by a subtractor circuit, the feedback signal from the second signal to generate an output signal.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of a front‑end circuitry according to some embodiments of the present disclosure.

FIG. 2 illustrates a schematic diagram of a front‑end circuitry according to some embodiments of the present disclosure.

FIG. 3A and FIG. 3B illustrates a schematic diagram of the buffer circuit in FIG. 1 or FIG. 2 according to some embodiments of the present disclosure.

FIG. 4 illustrates a schematic diagram of a front‑end circuitry according to some embodiments of the present disclosure.

FIG. 5 illustrates a schematic diagram of the buffer circuit in FIG. 4 according to some embodiments of the present disclosure.

FIG. 6 illustrates a flowchart of a signal conversion method according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuitry” may be a system formed with one or more circuits, and the term “circuit” may indicate an object, which is formed with one or more transistors and/or one or more active/passive elements according to a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

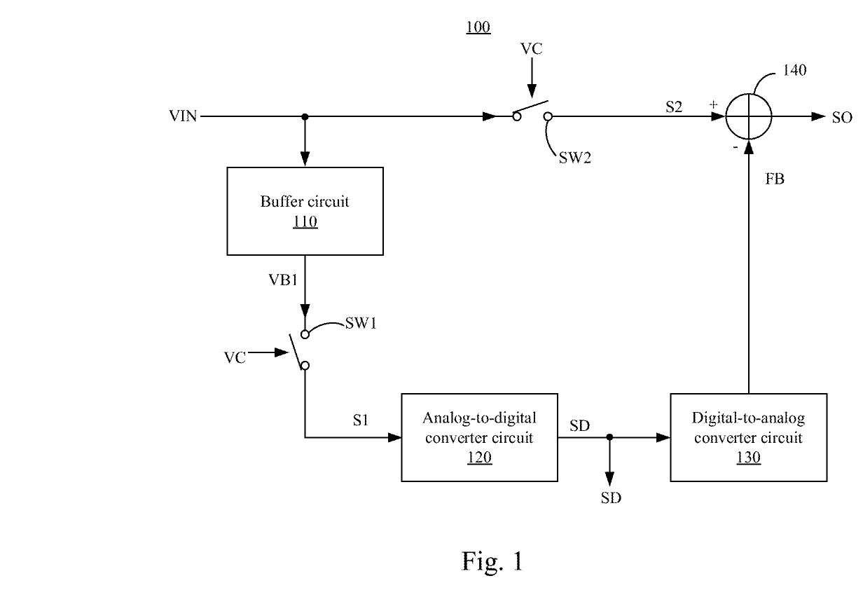

FIG. 1 illustrates a schematic diagram of a front‑end circuitry 100 according to some embodiments of the present disclosure. In different embodiments, the front‑end circuitry 100 may be applied in various types of analog‑to‑digital converter circuits and/or digital‑to‑analog converter circuits. For example, the front‑end circuitry 100 may be applied, but is not limited to, a multiplying digital‑to‑analog converter (MDAC) in a pipeline analog‑to‑digital converter.

The front‑end circuitry 100 includes a buffer circuit 110, a switch SW1, an analog‑to‑digital converter circuit 120, a digital‑to‑analog converter circuit 130, a switch SW2, and a subtractor circuit 140. The buffer circuit 110 is configured to generate a buffer signal VB1 according to an input signal SIN. The switch SW1 is configured to be turned on according to a control signal VC, in order to output the buffer signal VB1 as a signal S1. The analog‑to‑digital converter circuit 120 is configured to generate a digital code SD according to the signal S1. In some embodiments, the analog‑to‑digital converter circuit 120 may be, but is not limited to, a flash analog‑to‑digital converter.

The digital‑to‑analog converter circuit 130 is configured to generate a feedback signal FB according to the digital code SD. In some embodiments, the digital‑to‑analog converter circuit 130 may be, but is not limited to, a capacitive digital‑to‑analog converter. The capacitive digital‑to‑analog converter may include a capacitor array circuit (not shown) and a switching circuit (not shown), in which the switching circuit may be controlled by the digital code SD to switch connections in the capacitor array circuit to perform capacitor charge and discharge operations, in order to generate a corresponding feedback signal FB. The switch SW2 is configured to be turned on according to the control signal VC, in order to output a signal S2 according to the input signal SIN. The subtractor circuit 140 is configured to subtract the feedback signal FB from the signal S2 to generate an output signal SO.

As described above, the analog‑to‑digital converter circuit 120 may be a flash analog‑to‑digital converter. Generally, a flash analog‑to‑digital converter may include comparator circuits. In practical applications, switching of the comparator circuits and the switch SW1 may cause kickback noise on the input signal SIN. By arranging the buffer circuit 110 to indirectly isolate the switch SW1, the influence of the kickback noise on the input signal SIN can be reduced. Furthermore, as the analog‑to‑digital converter circuit 120 usually has a certain error tolerance range, a phase difference caused by the buffer circuit 110 to the input signal SIN may be adjusted to an acceptable range without affecting original circuit operation. Therefore, by utilizing the buffer circuit 110, unexpected disturbance to the input signal SIN caused by the analog‑to‑digital converter circuit 120 may be reduced, thereby improving the quality of the digital code SD and the output signal SO.

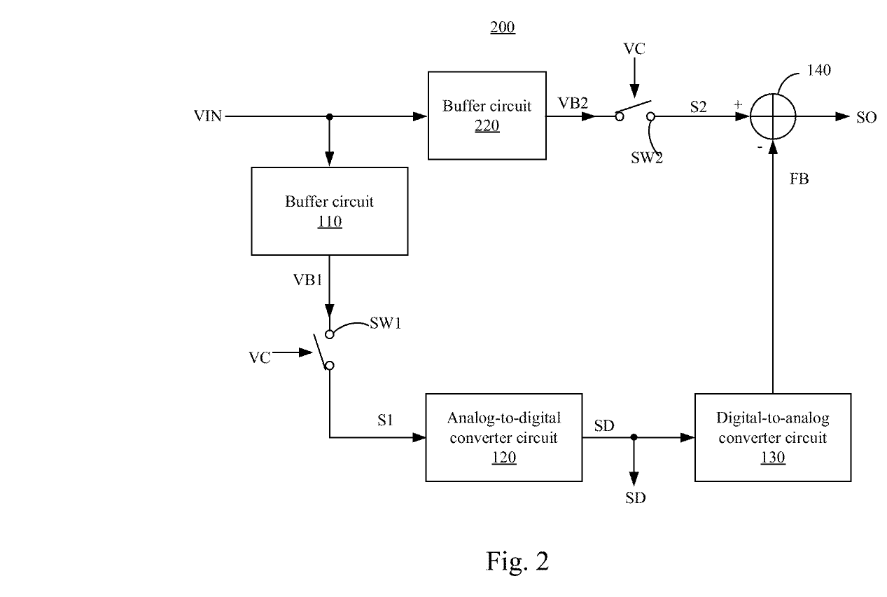

FIG. 2 illustrates a schematic diagram of a front‑end circuitry 200 according to some embodiments of the present disclosure. Compared with the example in FIG. 1, in this example, the front‑end circuitry 200 further includes a buffer circuit 220. The buffer circuit 220 is configured to generate a buffer signal VB2 according to the input signal SIN, and the switch SW2 is further configured to be turned on according to the control signal VC to output the buffer signal VB2 as a signal S2.

In some embodiments, specification requirement(s) of the buffer circuit 110 may be lower than specification requirement(s) of the buffer circuit 220. In some embodiments, the above specification requirement(s) may include, but are not limited to, bandwidth, linearity, area, current consumption, rated voltage, and the like. For example, bandwidth of the buffer circuit 110 is lower than bandwidth of the buffer circuit 220. Linearity of the buffer circuit 110 is lower than linearity of the buffer circuit 220. Area of the buffer circuit 110 is smaller than area of the buffer circuit 220. Current consumption of the buffer circuit 110 is lower than current consumption of the buffer circuit 220. A rated voltage of the buffer circuit 110 is lower than a rated voltage of the buffer circuit 220. In practical applications, the digital‑to‑analog converter circuit 130 and switching of the switch SW2 may also cause kickback noise on the input signal SIN. Therefore, by arranging the buffer circuit 220 to indirectly isolate the switch SW2, influence of kickback noise from the digital‑to‑analog converter circuit 130 and the switch SW2 can be reduced. On the other hand, as described above, as the analog‑to‑digital converter circuit 120 has a certain error tolerance range, a lower‑quality buffer signal VB1 may be acceptable. Therefore, in design considerations, specification requirement(s) of the buffer circuit 110 can be reduced to save circuit area, power consumption and/or cost. Meanwhile, in order to effectively reduce influence of kickback noise introduced by switching of the digital‑to‑analog converter circuit 130 and the switch SW2, a buffer circuit having higher specification requirement(s) may be employed to implement the buffer circuit 220, in order to further improve quality of the output signal SO.

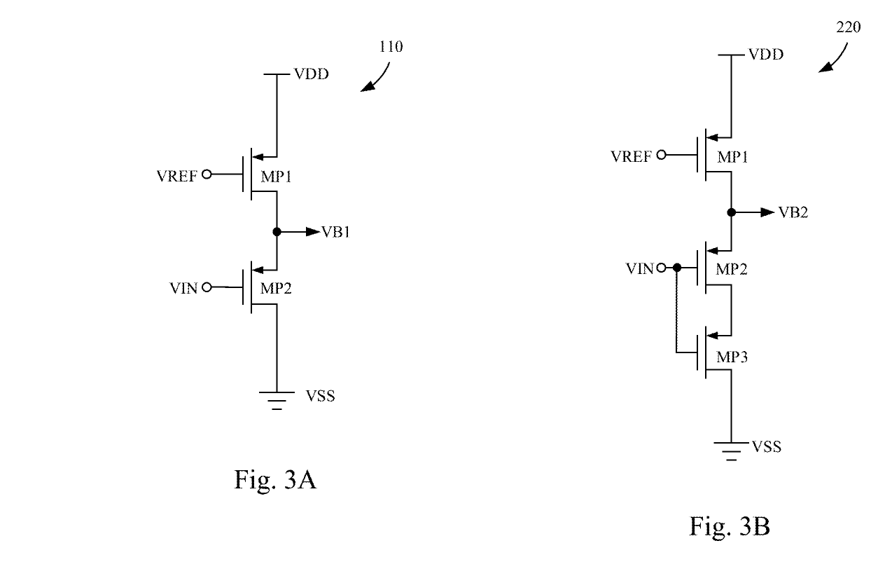

FIG. 3A illustrates a schematic diagram of the buffer circuit 110 in FIG. 1 or FIG. 2 according to some embodiments of the present disclosure. In some embodiments, the buffer circuit 110 may be an analog buffer circuit, for example, but not limited to, a source follower circuit. For example, the buffer circuit 110 includes a transistor MP1 and a transistor MP2. A first terminal (e.g., a source) of the transistor MP1 receives a supply voltage VDD, a second terminal (e.g., a drain) of the transistor MP1 is coupled to a first terminal of the transistor MP2, and a control terminal (e.g., a gate) of the transistor MP1 receives a reference voltage VREF. A first terminal of the transistor MP2 outputs the buffer signal VB1, a second terminal of the transistor MP2 receives a supply voltage VSS, and a control terminal of the transistor MP2 receives an input signal VIN. With the above arrangement, the transistor MP1 may be biased by the reference voltage VREF to operate as a current source to drive the transistor MP2, and the transistor MP2 may generate the buffer signal VB1 according to the input signal VIN.

FIG. 3B illustrates a schematic diagram of the buffer circuit 220 in FIG. 2 according to some embodiments of the present disclosure. In some embodiments, the buffer circuit 220 may be an analog buffer circuit, for example but not limited to, a source follower circuit. Compared with the buffer circuit 110, the buffer circuit 220 further includes a transistor MP3. The transistor MP2 and the transistor MP3 are coupled in series and coupled to the transistor MP1. In greater detail, in this example, the first terminal of the transistor MP2 is configured to output the buffer signal VB2, and the second terminal of the transistor MP2 is coupled to a first terminal of the transistor MP3. A second terminal of the transistor MP3 receives the supply voltage VSS, and a control terminal of the transistor MP3 receives the input signal VIN. Thus, the transistor MP2 and the transistor MP3 may generate the buffer signal VB2 according to the input signal VIN. Compared with FIG. 3A, in this example, since potential levels of respective terminals of the transistor MP2 vary with the input signal VIN, voltage differences between terminals of the transistor MP2 are relatively fixed, so that linearity of the transistor MP2 can be improved to generate the buffer signal VB2 having better quality.

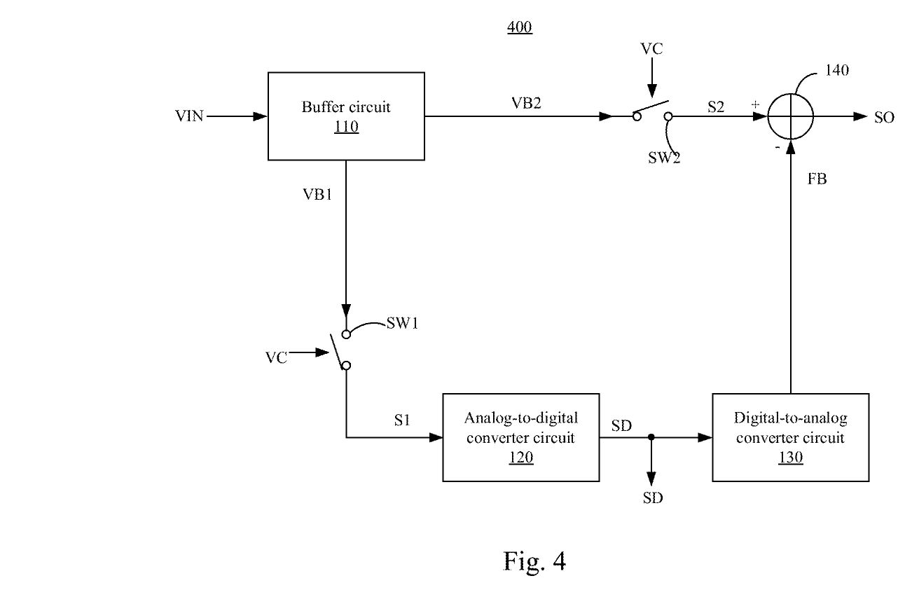

FIG. 4 illustrates a schematic diagram of a front‑end circuitry 400 according to some embodiments of the present disclosure. Compared with the example of FIG. 1, in this example, the buffer circuit 110 is further configured to generate the buffer signal VB2 according to the input signal SIN, and the switch SW2 is further turned on according to the control signal VC to output the buffer signal VB2 as a signal S2. In other words, in this example, the buffer circuit 110 may be configured to generate the buffer signal VB1 and the buffer signal VB2 in FIG. 2. Equivalently, the buffer circuit 110 and the buffer circuit 220 in FIG. 2 may be integrated into the buffer circuit 110 of FIG. 4.

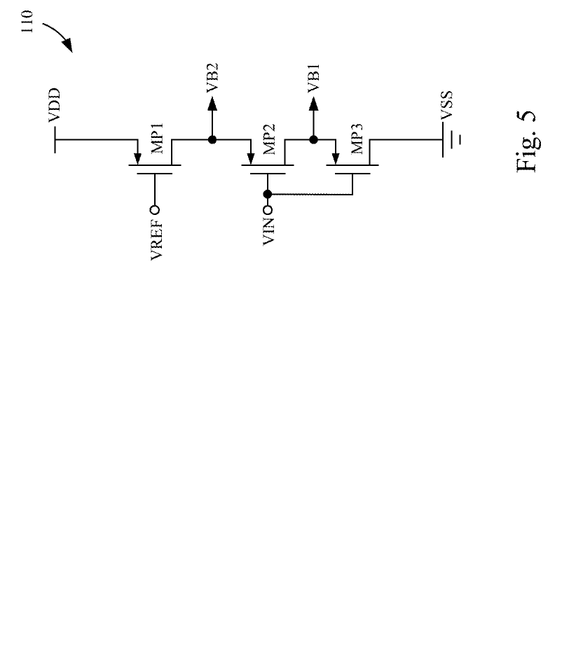

FIG. 5 illustrates a schematic diagram of the buffer circuit 110 in FIG. 4 according to some embodiments of the present disclosure. Compared with FIG. 3B, in this example, the second terminal of the transistor MP2 may be configured to output the buffer signal VB1 according to the input signal VIN. In this example, although the transistor MP1, the transistor MP2 and the transistor MP3 are arranged in the same path, since the transistor MP2 is coupled between the transistor MP1 and the transistor MP3 (that is, arranged between a node that outputs the buffer signal VB1 and a node that outputs the buffer signal VB2), the transistor MP2 may provide a certain buffering effect for the buffer signal VB1 and the buffer signal VB2 to reduce influence of kickback noise.

In other embodiments, the first terminal of the transistor MP2 may be changed to output the buffer signal VB1 and the second terminal of the transistor MP2 may be changed to output the buffer signal VB2. Various circuit arrangements that are able to generate the corresponding buffer signal VB1 and buffer signal VB2 are within the contemplated scope of the present disclosure. In the examples of FIG. 3A, FIG. 3B and FIG. 5, each of the transistors MP1, MP2 and MP3 may be a P‑type transistor. In other examples, the circuit arrangements of FIG. 3A, FIG. 3B and FIG. 5 may be implemented with transistors having other conductivity types. Therefore, the above arrangements regarding the buffer circuit 110 and/or the buffer circuit 220 are given for illustrative purposes, and the present disclosure is not limited thereto.

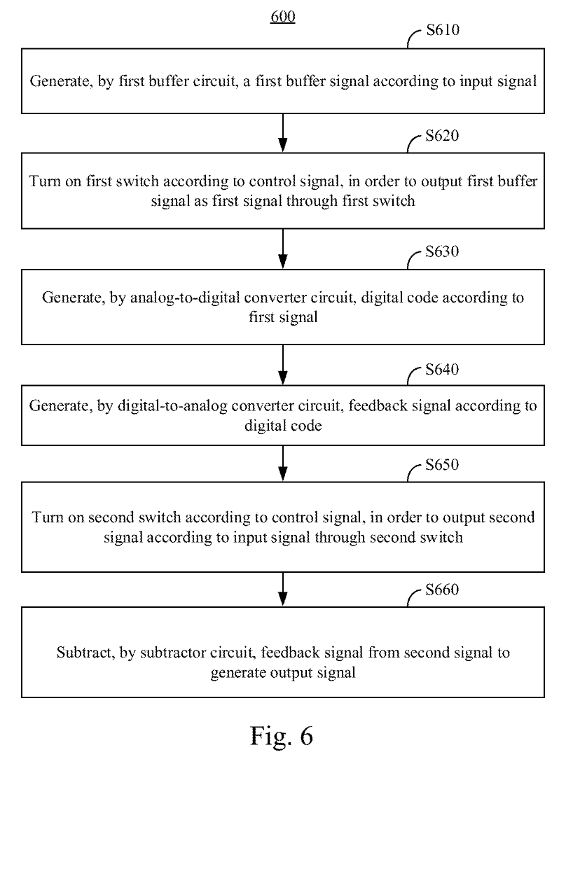

FIG. 6 illustrates a flowchart of a signal conversion method 600 according to some embodiments of the present disclosure. In operation S610, a first buffer signal is generated by a first buffer circuit according to an input signal. In operation S620, a first switch is turned on according to a control signal, in order to output the first buffer signal as a first signal through the first switch. In operation S630, a digital code is generated by an analog‑to‑digital converter circuit according to the first signal. In operation S640, a feedback signal is generated by a digital‑to‑analog converter circuit according to the digital code. In operation S650, a second switch is turned on according to the control signal, in order to output a second signal according to the input signal through the second switch. In operation S660, the feedback signal is subtracted from the second signal by a subtractor circuit to generate an output signal.

Operations related to the signal conversion method 600 may be understood with reference to the descriptions of the above embodiments and thus will not be repeated herein. Operations in the signal conversion method 600 include exemplary operations, but the operations in the signal conversion method 600 are not necessarily performed in the order described above. Operations in the signal conversion method 600 may be added, replaced, changed order, and/or eliminated, or one or more operations in the signal conversion method 600 may be executed simultaneously or partially simultaneously as appropriate, in accordance with the spirit and scope of various embodiments of the present disclosure.

As described above, the front‑end circuitry and the signal conversion method provided by some embodiments of the present disclosure may employ one or more buffer circuits to reduce the influence of kickback noise, reduce overall circuit cost, and improve quality of generated signals.

Various functional components or blocks have been described herein. As will be appreciated by persons skilled in the art, in some embodiments, the functional blocks will preferably be implemented through circuits (either dedicated circuits, or general-purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of the present disclosure are all consequently viewed as being embraced by the scope of the present disclosure.

What is claimed is:

1. A front‑end circuitry, comprising:
a first buffer circuit configured to generate a first buffer signal according to an input signal;
a first switch configured to be turned on according to a control signal, in order to output the first buffer signal as a first signal;
an analog‑to‑digital converter circuit configured to generate a digital code according to the first signal;
a digital‑to‑analog converter circuit configured to generate a feedback signal according to the digital code;
a second switch configured to be turned on according to the control signal, in order to output a second signal according to the input signal; and
a subtractor circuit configured to subtract the feedback signal from the second signal to generate an output signal.

2. The front‑end circuitry of claim 1, further comprising:
a second buffer circuit configured to generate a second buffer signal according to the input signal, wherein the second switch is configured to be turned on according to the control signal, in order to output the second buffer signal as the second signal.

3. The front‑end circuitry of claim 2, wherein a specification requirement of the first buffer circuit is lower than a specification requirement of the second buffer circuit.

4. The front‑end circuitry of claim 2, wherein a bandwidth of the first buffer circuit is lower than a bandwidth of the second buffer circuit.

5. The front‑end circuitry of claim 2, wherein linearity of the first buffer circuit is lower than linearity of the second buffer circuit.

6. The front‑end circuitry of claim 2, wherein an area of the first buffer circuit is smaller than an area of the second buffer circuit.

7. The front‑end circuitry of claim 2, wherein the second buffer circuit comprises:
a first transistor configured to be biased by a reference voltage; and
a plurality of second transistors, wherein the plurality of second transistors are coupled in series and coupled to the first transistor and are configured to generate the second buffer signal according to the input signal.

8. The front‑end circuitry of claim 2, wherein current consumption of the first buffer circuit is lower than current consumption of the second buffer circuit.

9. The front‑end circuitry of claim 2, wherein a rated voltage of the first buffer circuit is lower than a rated voltage of the second buffer circuit.

10. The front‑end circuitry of claim 1, wherein the first buffer circuit is further configured to generate a second buffer signal according to the input signal, and the second switch is configured to be turned on according to the control signal to output the second buffer signal as the second signal.

11. The front‑end circuitry of claim 10, wherein the first buffer circuit comprises:
a first transistor configured to be biased by a reference voltage;
a second transistor configured to generate the first buffer signal according to the input signal; and
a third transistor coupled between the first transistor and the second transistor and configured to generate the second buffer signal according to the input signal.

12. A signal conversion method, comprising:
generating, by a first buffer circuit, a first buffer signal according to an input signal;
turning on a first switch according to a control signal, in order to output the first buffer signal as a first signal through the first switch;
generating, by an analog‑to‑digital converter circuit, a digital code according to the first signal;
generating, by a digital‑to‑analog converter circuit, a feedback signal according to the digital code;
turning on a second switch according to the control signal, in order to output a second signal according to the input signal through the second switch; and
subtracting, by a subtractor circuit, the feedback signal from the second signal to generate an output signal.

13. The signal conversion method of claim 12, further comprising:
generating, by a second buffer circuit, a second buffer signal according to the input signal,
wherein turning on the second switch according to the control signal, in order to output the second signal according to the input signal through the second switch comprises:
turning on the second switch according to the control signal, in order to output the second buffer signal as the second signal through the second switch.

14. The signal conversion method of claim 13, wherein a specification requirement of the first buffer circuit is lower than a specification requirement of the second buffer circuit.

15. The signal conversion method of claim 13, wherein a bandwidth of the first buffer circuit is lower than a bandwidth of the second buffer circuit.

16. The signal conversion method of claim 13, wherein linearity of the first buffer circuit is lower than linearity of the second buffer circuit.

17. The signal conversion method of claim 13, wherein an area of the first buffer circuit is smaller than an area of the second buffer circuit.

18. The signal conversion method of claim 13, wherein current consumption of the first buffer circuit is lower than current consumption of the second buffer circuit.

19. The signal conversion method of claim 13, wherein a rated voltage of the first buffer circuit is lower than a rated voltage of the second buffer circuit.

20. The signal conversion method of claim 12, further comprising:
generating, by the first buffer circuit, a second buffer signal according to the input signal,
wherein turning on the second switch according to the control signal, in order to output the second signal according to the input signal through the second switch comprises:
turning on the second switch according to the control signal, in order to output the second buffer signal as the second signal through the second switch.
